(19) United States
(12) Patent Application Publication
(10) Pub. No.: US 2026/0047471 A1
(43) Pub. Date: Feb. 12, 2026

(54) CONDUCTIVE POLYMER MATERIALS FOR HYBRID BONDING

(71) Applicant: ADEIA SEMICONDUCTOR BONDING TECHNOLOGIES INC., San Jose, CA (US)

(72) Inventors: Pawel Mrozek, San Jose, CA (US); Gaius Gillman Fountain, JR., Youngsville, NC (US)

(21) Appl. No.: 18/902,623

(22) Filed: Sep. 30, 2024

Related U.S. Application Data
(60) Provisional application No. 63/680,529, filed on Aug. 7, 2024.

(51) Int. Cl. H01L 23/00

(52) U.S. Cl. CPC H01L 24/05; H01L 24/03; H01L 24/08; H01L 24/80; H01L 2224/03416; H01L 2224/03845; H01L 2224/05567; H01L 2224/0569; H01L 2224/08145; H01L 2224/80895; H01L 2224/80896; H01L 2224/80935

(57) ABSTRACT

A structure includes a first substrate, a second substrate, and an interface region. The first substrate includes a first layer having at least one electrically conductive first portion and at least one electrically insulative second portion. The second substrate includes a second layer having at least one electrically conductive third portion and at least one electrically insulative fourth portion. The interface region is between the first layer and the second layer and includes at least one electrically conductive polymer material.

### BACKGROUND

### Field

The field relates to systems and methods for wafer-to-wafer, die-to-die, and/or die-to-wafer hybrid bonding for semiconductor devices and optoelectronic devices.

### Description of the Related Art

Semiconductor elements, such as semiconductor wafers or integrated device dies, can be stacked and directly bonded to one another without an adhesive, thereby forming a bonded structure. Nonconductive (e.g., dielectric; semiconductor) surfaces can be made extremely smooth and treated to enhance direct, covalent bonding, even at room temperature and without application of pressure beyond contact. In some hybrid bonded structures, nonconductive field regions of the elements can be directly bonded to one another, and corresponding conductive contact structures can be directly bonded to one another.

For example, a semiconductor element can be mounted to a carrier, such as a package substrate, an interposer, a reconstituted wafer or element, a flat panel, a glass, etc. A semiconductor element can be stacked on top of the semiconductor element (e.g., a first integrated device die can be stacked on a second integrated device die). Each of the semiconductor elements can have conductive pads for mechanically and electrically bonding the semiconductor elements to one another with the conductive pads mechanically and electrically bonded to one another.

### SUMMARY

Certain implementations described herein provide a structure comprising a first substrate, a second substrate, and an interface region. The first substrate comprises a first layer having at least one electrically conductive first portion and at least one electrically insulative second portion. The second substrate comprises a second layer having at least one electrically conductive third portion and at least one electrically insulative fourth portion. The interface region is between the first layer and the second layer and comprises at least one electrically conductive polymer material.

Certain implementations described herein provide a structure comprises a first substrate having a first conductive feature comprising a first deposited electrically conductive polymer material. The structure further comprises a second substrate having a second conductive feature. The second substrate is hybrid bonded to the first substrate such that the second conductive feature is bonded to the first conductive feature.

Certain implementations described herein provide a method comprising providing a first substrate and a second substrate each comprising one or more electrically conductive surface portions and one or more electrically insulative surface portions. The one or more electrically conductive surface portions of at least one of the first substrate and the second substrate comprises an electrically conductive polymer material. The method further comprises hybrid bonding the first substrate and the second substrate with one another without an intervening adhesive. Hybrid bonding the first substrate and the second substrate comprises: contacting the one or more electrically conductive surface portions of the first substrate with the one or more electrically conductive surface portions of the second substrate and contacting the one or more electrically insulative surface portions of the first substrate with the one or more electrically insulative surface portions of the second substrate.

Certain implementations described herein provide a structure comprising an integrated device die comprising a substrate comprising at least one electrically conductive contact pad at least partially embedded in an electrically insulative layer. The electrically conductive contact pad comprises an electrically conductive polymer material configured to electrically connect to an opposing conductive feature.

### BRIEF DESCRIPTION OF THE DRAWINGS

Specific implementations will now be described with reference to the following drawings, which are provided by way of example, and not limitation.

FIG. 1A is a schematic cross-sectional side view of two elements prior to bonding in accordance with certain implementations described herein.

FIG. 1B is a schematic cross-sectional side view of the two elements of FIG. 1A after bonding in accordance with certain implementations described herein.

FIGS. 2A and 2B schematically illustrate two cross-sectional views of an example structure in accordance with certain implementations described herein.

FIG. 3A schematically illustrates various example intermediate structures for the first substrate in accordance with certain implementations described herein.

FIG. 3B is a flow diagram of an example method for forming the example structure in accordance with certain implementations described herein.

FIG. 4A schematically illustrates various example intermediate structures for the first substrate in accordance with certain implementations described herein.

FIG. 4B is a flow diagram of another example method for forming the example structure in accordance with certain implementations described herein.

FIG. 5A schematically illustrates various example intermediate structures for the first substrate in accordance with certain implementations described herein.

FIG. 5B is a flow diagram of another example method for forming the example structure in accordance with certain implementations described herein.

FIG. 6 schematically illustrates fabrication of another example structure in accordance with certain implementations described herein.

FIG. 7 schematically illustrates fabrication of another example structure in accordance with certain implementations described herein.

FIG. 8A schematically illustrates various example intermediate structures for the first substrate in accordance with certain implementations described herein.

FIG. 8B is a flow diagram of another example method for forming the example structure in accordance with certain implementations described herein.

### DETAILED DESCRIPTION

Various implementations disclosed herein relate to directly bonded structures in which two or more elements can be directly bonded to one another without an intervening adhesive. In some embodiments, direct bonding can involve bonding of a single material on one element and a single material on the other element, where the single materials on the different elements may or may not be the same. Direct bonding can also involve bonding of multiple materials on one element to multiple materials on the other element (e.g., hybrid bonding).

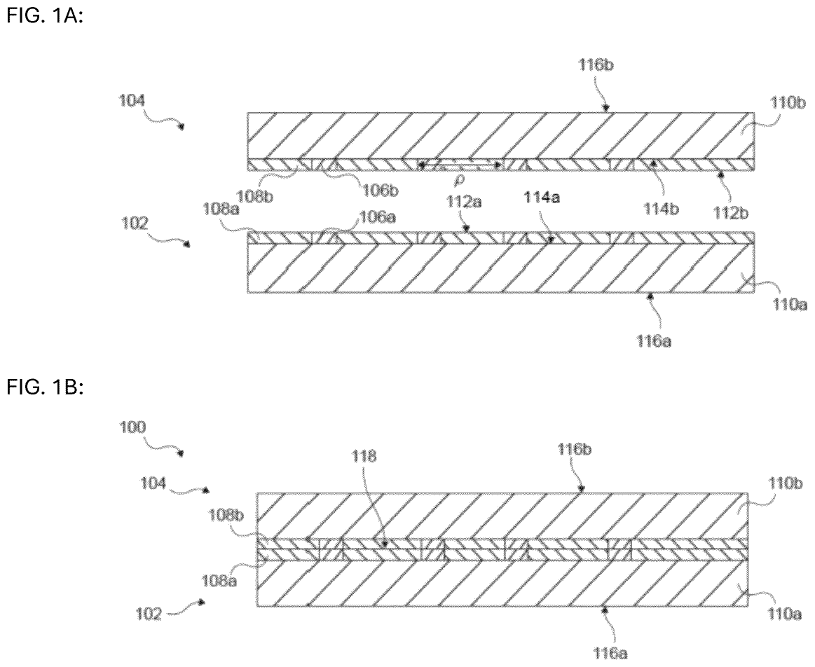

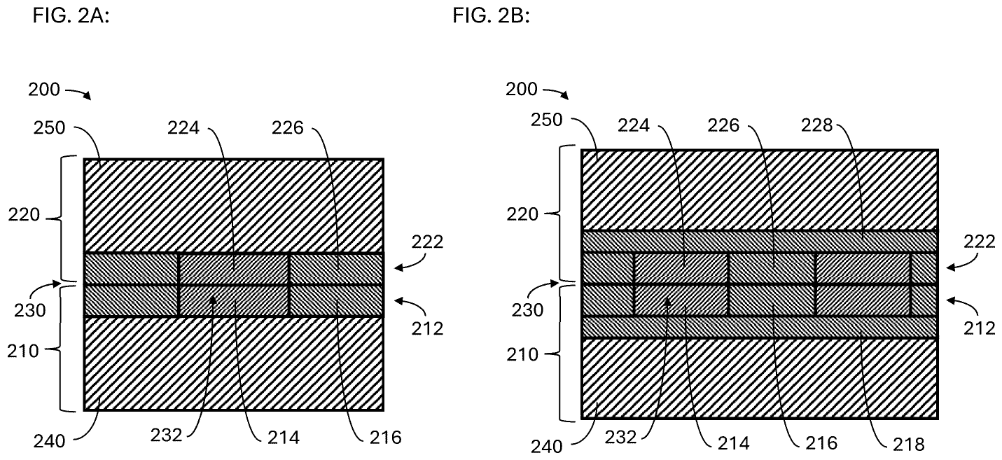

FIGS. 1A and 1B schematically illustrate cross-sectional side views of two elements 102, 104 prior to and after, respectively, a typical bonding process for forming a hybrid bonded structure 100 without an intervening adhesive (which may sometimes be referred to as a “direct hybrid bonded structure”). As used herein, the term “hybrid bonding” refers to a species of direct bonding in which there are both i) nonconductive features directly bonded to nonconductive features, and ii) conductive features directly bonded to conductive features. In the implementations disclosed herein, for example, the conductive features can comprise electrically conductive oxide material(s). In some implementations, the conductive features can serve as signal, power, or ground connections between two elements. In other implementations, at least some of the conductive features may be electrically isolated such that they do not serve as electrical connections between elements. As shown in FIGS. 1A and 1B, the bonded structure 100 can comprise a first element 102 and a second element 104 that are directly bonded to one another at a bond interface 118 without an intervening adhesive. The first and second elements 102, 104 can comprise microelectronic elements (e.g., semiconductor elements, including, for example, integrated device dies, wafers, passive devices, individual active devices such as power switches, etc.) and/or optical elements or devices (e.g., photodiodes; light emitting diodes (LEDs); quantum dot light emitting diodes (QLEDs); lasers; vertical-cavity surface-emitting lasers (VCSELs); transparency control pixels; liquid crystal pixels; adaptive optics; waveguides) that are stacked on or bonded to one another to form the bonded structure 100. For example, one or both of the first and second elements 102, 104 can comprise a thinned substrate or integrated device die having a thickness in a range of about 10 μm to 700 μm, in a range of about 10 μm to 300 μm, in a range of about 30 μm to 300 μm, or in a range of about 50 μm to 300 μm. Conductive features 106a (e.g., contact pads, exposed ends of vias (e.g., TSVs), or a through substrate electrodes) of the first element 102 can be electrically connected to corresponding conductive features 106b of the second element 104. In certain implementations, the conductive features 106a comprise an electrically conductive material that is optically transparent (e.g., indium tin oxide (ITO), indium-doped zinc oxide (IZO), tin oxide (SnO₂)) or optically semi-transparent (e.g., metal or polysilicon layer having a thickness less than 50 nanometers). Accordingly, as explained herein, the conductive features 106a can comprise conductive oxide materials in various implementations.

While FIGS. 1A and 1B schematically illustrate two elements 102, 104, any suitable number of elements can be stacked in the bonded structure 100 in accordance with certain implementations described herein. For example, a third element (not shown) can be stacked on the second element 104, a fourth element (not shown) can be stacked on the third element, and so forth. Additionally or alternatively, one or more additional elements (not shown) can be stacked laterally adjacent one another along the first element 102. In certain implementations, the laterally stacked additional element can be smaller than the second element 104 (e.g., the laterally stacked additional element can be two times smaller than the second element 104).

In certain implementations, the elements 102, 104 are directly bonded to one another without an adhesive. Bonding layers can be provided on front sides and/or back sides of the first and second elements 102, 104. For example, as schematically illustrated in FIGS. 1A and 1B, a first bonding layer 108a of the first element 102 can comprise a nonconductive field region of the first element 102 that includes a nonconductive or dielectric material (e.g., a dielectric material, such as silicon oxide, silicon nitride, silicon carbide, or an undoped semiconductor material, such as undoped silicon) and a second bonding layer 108b of the second element 104 can comprise a nonconductive field region of the second element 104 that includes a nonconductive or dielectric material (e.g., a dielectric material, such as silicon oxide/nitride/carbide, or an undoped semiconductor material, such as undoped silicon). The first and second bonding layers 108a, 108b can be disposed on respective front sides 114a, 114b of device portions 110a, 110b, such as semiconductor (e.g., silicon) portions, of the first and second elements 102, 104. Active devices (e.g., electrical devices; optical devices) and/or circuitry can be patterned and/or otherwise disposed in or on the device portions 110a, 110b, disposed at or near the front sides 114a, 114b of the device portions 110a, 110b, and/or at or near opposite backsides 116a, 116b of the device portions 110a, 110b. In other embodiments, such as the embodiments disclosed hereinbelow, the field regions of the bonding layer may include conductive materials (e.g., ITO) that are patterned to be isolated from devices, such that they the field regions do not serve as electrical connections.

The first and second bonding layers 108a, 108b can be directly bonded to one another without an adhesive (e.g., using dielectric-to-dielectric bonding techniques, or conductor-to-conductor bonding techniques described in more detail hereinbelow). For example, non-conductive or dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In certain implementations, the dielectric materials do not comprise polymer materials, such as epoxy, resin or molding materials. In embodiments that include isolated conductive materials in the field regions for bonding, the isolation can be achieved by gaps or by dielectric materials, and in the latter case the dielectric materials can also be directly bonded in a hybrid bonding process.

In certain implementations, the device portions 110a, 110b can have significantly different coefficients of thermal expansion (CTEs) defining a heterogenous structure. The CTE difference between the device portions 110a, 110b, and particularly between bulk semiconductor (e.g., typically single crystal) portions of the device portions 110a, 110b can be greater than 5 ppm or greater than 10 ppm. For example, the CTE values for certain materials compatible with certain implementations described herein are in a range of 2 ppm to 10 ppm and the CTE difference between the device portions 110a, 110b can be in a range of 1 ppm to 10 ppm, 2 ppm to 10 ppm, or 5 ppm to 40 ppm. In certain implementations, one of the device portions 110a, 110b can comprise optoelectronic single crystal materials, including perovskite materials, that are useful for optical piezoelectric or pyroelectric applications, and the other of the device portions 110a, 110b can comprise a more conventional substrate material. For example, one of the device portions 110a, 110b can comprise lithium tantalate (LiTaO₃) or lithium niobate (LiNbO₃), and the other one of the device portions 110a, 110b can comprise silicon (Si), quartz, fused silica glass, sapphire, or a glass. In certain other implementations, one of the device portions 110a, 110b comprises a III-V single semiconductor material, such as gallium arsenide (GaAs) or gallium nitride (GaN), and the other one of the device portions 110a, 110b comprises a non-III-V semiconductor material, such as silicon (Si), or another materials with similar CTE, such as quartz, fused silica glass, sapphire, or a glass.

In certain implementations, hybrid bonds can be formed without an intervening adhesive. For example, bonding surfaces 112a, 112b of the nonconductive field regions of the bonding layers 108a, 108b can be polished to a high degree of smoothness (e.g., using chemical mechanical polishing (CMP)). The roughness of the polished surfaces 112a, 112b can be less than 30 Å rms. For example, the roughness of the polished surfaces 112a, 112b can be in a range of about 0.1 Å rms to 15 Å rms, 0.5 Å rms to 10 Å rms, or 1 Å rms to 5 Å rms. In other embodiments, as explained herein, one or both bonding surfaces 112a, 112b may comprise conductive oxides that are not be planarized, or may be planarized to a lesser degree. In such embodiments, the roughness of the unpolished surfaces 112a, 112b can be greater than 30 Å rms. The surfaces 112a, 112b can be cleaned and exposed to plasma and/or chemical etchants to activate the surfaces 112a, 112b. In certain implementations, the surfaces 112a, 112b can be terminated with a species after activation or during activation (e.g., during the plasma and/or etch processes). In some implementations, such as the conductive oxide bonding surfaces disclosed herein, one or both surfaces 112a, 112b may not be activated and/or terminated. Without being limited by theory, in certain implementations, the activation process can be performed to break chemical bonds at the surfaces 112a, 112b, and the termination process can provide additional chemical species at the surfaces 112a, 112b that improves the bonding energy during direct bonding. In certain implementations, the activation and termination are provided in the same step (e.g., a plasma to activate and terminate the surfaces 112a, 112b). In certain other implementations, the surfaces 112a, 112b are terminated in a separate treatment from the activation process to provide the additional species for direct bonding. In certain implementations, the terminating species can comprise nitrogen. For example, one or both of the surfaces 112a, 112b can be exposed to a nitrogen-containing plasma (see, e.g., U.S. Pat. No. 7,387,944). Further, in certain implementations, one or both of the surfaces 112a, 112b are exposed to fluorine. For example, there may be one or multiple fluorine peaks at or near a bond interface 118 between the first and second elements 102, 104. Thus, in the directly bonded structure 100, the bond interface 118 between two nonconductive materials (e.g., the first and second bonding layers 108a, 108b) can comprise a very smooth interface with higher nitrogen content and/or fluorine peaks at the bond interface 118 (see, e.g., U.S. Pat. No. 9,564,414). Additional examples of activation and/or termination treatments may be found throughout U.S. Pat. Nos. 9,564,414; 9,391,143; and 10,434,749, the entire contents of each of which are incorporated by reference herein in their entirety and for all purposes. The roughness of the polished surfaces 112a, 112b can be slightly rougher (e.g., about 1 Å rms to 30 Å rms, 3 Å rms to 20 Å rms, or possibly rougher) after an activation process.

In certain implementations, the conductive features 106a of the first element 102 are directly bonded to the corresponding conductive features 106b of the second element 104. For example, a hybrid bonding technique can be used to provide conductor-to-conductor direct bonds along the bond interface 118 that includes covalently direct bonded non-conductive-to-non-conductive (e.g., dielectric-to-dielectric) surfaces, prepared as described herein. In typical implementations that employ metal conductive features, the conductor-to-conductor (e.g., conductive feature 106a to conductive feature 106b) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes. In hybrid bonding implementations described herein, conductive features are provided within the nonconductive field regions of the first and second bonding layers 108a, 108b, and both conductive and nonconductive features are prepared for direct bonding, such as by the planarization, activation and/or termination treatments described herein. Thus, the first and second bonding layers 108a, 108b prepared for direct bonding includes both conductive and nonconductive features.

For example, surfaces 112a, 112b of the nonconductive (e.g., dielectric) field regions (for example, inorganic dielectric surfaces) can be prepared and directly bonded to one another without an intervening adhesive as explained herein. Conductive contact features (e.g., conductive features 106a, 106b) can be at least partially surrounded by nonconductive (e.g., dielectric) field regions within the first and second bonding layers 108a, 108b and can directly bond to one another without an intervening adhesive. In certain implementations, the conductive features 106a, 106b can comprise discrete pads or traces at least partially embedded in the nonconductive material of the bonding layers 108a, 108b. In certain implementations, the conductive contact features comprise exposed contact surfaces of through substrate vias (e.g., through silicon vias (TSVs)). In some implementations, the conductive features 106a, 106b can be substantially flush with or protrude relative to the exterior surfaces of the nonconductive portions. In other implementations, the respective conductive features 106a, 106b can be recessed below the exterior (e.g., upper) surfaces (e.g., nonconductive bonding surfaces 112a, 112b) of the nonconductive portions of the first and second bonding layers 108a, 108b. For example, the recess can be less than 30 nm, less than 20 nm, less than 15 nm, or less than 10 nm, in a range of 2 nm to 20 nm, or in a range of 4 nm to 10 nm. In certain implementations, prior to direct bonding, the recesses in the opposing elements 102, 104 can be sized such that the total gap between opposing contact pads is less than 15 nm or less than 10 nm.

In hybrid bonding implementations, particularly where the conductive features 106a, 106b comprise metal materials, the first and second bonding layers 108a, 108b are directly bonded to one another without an adhesive at room temperature and, subsequently, the bonded structure 100 can be annealed. Upon annealing, the conductive features 106a, 106b can expand and contact one another to form a metal-to-metal direct bond. In such implementations, the materials of the conductive features 106a, 106b interdiffuse with one another during the annealing process. Beneficially, the use of Direct Bond Interconnect (DBI®) techniques commercially available from Adeia of San Jose, CA, can enable high density of conductive features 106a, 106b to be connected across the direct bond interface 118 (e.g., small or fine pitches for regular arrays). In certain implementations, the pitch of the conductive features 106a, 106b (e.g., conductive traces embedded in the bonding layer 108a, 108b of one of the bonded elements 102, 104) can be less than 100 microns or less than 10 microns or even less than 2 microns. For some applications, the ratio of the pitch of the conductive features 106a, 106b to one of the dimensions (e.g., a diameter) of the bonding pad is less than is less than 20, or less than 10, or less than 5, or less than 3 and sometimes desirably less than 2. In other applications, the width of the conductive traces embedded in the bonding layer 108a, 108b of one of the bonded elements 102, 104 is in a range between 0.1 micron to 20 microns (e.g., in a range of 0.3 micron to 3 microns). In typical implementations of hybrid bonded structures, the conductive features 106a, 106b and/or traces comprise copper or copper alloys, gold and gold alloys, nickel and nickel alloys, aluminum and aluminum alloys, although other metals and alloys may be suitable. For example, the conductive features, such as the conductive features 106a, 106b, can comprise fine-grain metal (e.g., a fine-grain copper). In the implementations disclosed herein, the conductive features 106a, 106b can comprise conductive oxide material(s) at least at the bond interface.

Thus, in direct bonding processes, the first element 102 can be directly bonded to the second element 104 without an intervening adhesive. In certain implementations, the first element 102 comprises a singulated element, such as a singulated integrated device die. In certain other implementations, the first element 102 comprises a carrier or substrate (e.g., a wafer) that includes a plurality (e.g., tens, hundreds, or more) of device regions that, when singulated, form a plurality of integrated device dies. Similarly, in certain implementations, the second element 104 comprises a singulated element, such as a singulated integrated device die. In certain other implementations, the second element 104 comprises a carrier or substrate (e.g., a wafer). Certain implementations disclosed herein can accordingly apply to wafer-to-wafer (W2W), die-to-die (D2D), or die-to-wafer (D2W), wafer to flat panel (W2FP), die to flat panel (D2FP), flat panel to flat panel (FP2FP) bonding processes. In wafer-to-wafer (W2W) processes, two or more wafers can be directly bonded to one another (e.g., hybrid bonded) and singulated using a suitable singulation process. After singulation, side edges of the singulated structure (e.g., the side edges of the two bonded elements 102, 104) can be substantially flush and can include markings indicative of the common singulation process for the bonded structure (e.g., saw markings if a saw singulation process is used).

As explained herein, the first and second elements 102, 104 can be directly bonded to one another without an adhesive, which is different from a deposition process and results in a structurally different interface compared to a deposition. In certain implementations, a width of the first element 102 in the bonded structure is similar to a width of the second element 104. In certain other implementations, a width of the first element 102 in the bonded structure 100 is different from a width of the second element 104. Similarly, the width or area of the larger of the first and second elements 102, 104 in the bonded structure can be at least 10% larger than the width or area of the smaller of the first and second elements 102, 104. The first and second elements 102, 104 can accordingly comprise non-deposited elements. Further, the directly bonded structures 100, unlike the deposited layers, can include a defect region along the bond interface 118 in which nanometer-scale voids (e.g., nanovoids) are present. The nanovoids can be formed due to activation of the bonding surfaces 112a, 112b (e.g., exposure to a plasma). As explained herein, the bond interface 118 can include concentration of materials from the activation and/or last chemical treatment processes. For example, in certain implementations that utilize a nitrogen plasma for activation, a nitrogen peak can be formed at the bond interface 118. The nitrogen peak can be detectable using secondary ion mass spectroscopy (SIMS) techniques. In certain implementations, for example, a nitrogen termination treatment (e.g., exposing the bonding surface to a nitrogen-containing plasma) can replace OH groups of a hydrolyzed (OH-terminated) surface with NH₂, NO, or NO₂ molecules, yielding a nitrogen-terminated surface. In certain implementations that utilize an oxygen plasma for activation, an oxygen peak can be formed at the bond interface 118. In certain implementations, the bond interface 118 can comprise silicon oxynitride, silicon oxycarbonitride, or silicon carbonitride. As explained herein, the direct bond can comprise a covalent bond, which is stronger than van Der Waals bonds. The bonding layers 108a, 108b can also comprise polished surfaces 112a, 112b that are planarized to a high degree of smoothness.

In implementations that utilize hybrid bonding techniques with metallic pads (e.g., copper pads), the metal-to-metal bonds between the conductive features 106a, 106b can be joined such that metal grains grow into each other across the bond interface 118. In certain implementations, the metal is or includes copper, which can have grains oriented along the <111> crystal plane for improved copper diffusion across the bond interface 118. In certain implementations, the conductive features 106a, 106b include nanotwinned copper grain structure, which can aid in merging the conductive features during anneal. The bond interface 118 can extend substantially entirely to at least a portion of the bonded conductive features 106a, 106b, such that there is substantially no gap between the nonconductive bonding layers 108a, 108b at or near the bonded conductive features 106a, 106b. In certain implementations, a barrier layer may be provided under and/or laterally surrounding the conductive features 106a, 106b (e.g., which may include copper). In some embodiments disclosed herein, the conductive features 106a, 106b can comprise conductive oxide material(s), with grains growing across the bond interface upon annealing. In certain other implementations, however, there may be no barrier layer under the conductive features 106a, 106b, for example, as described in U.S. Pat. No. 11,195,748, which is incorporated by reference herein in its entirety and for all purposes.

Beneficially, the use of the hybrid bonding techniques described herein can enable extremely fine pitch between adjacent conductive features 106a, 106b, and/or small pad sizes. For example, in certain implementations, the pitch p (e.g., the distance from edge-to-edge or center-to-center, as shown in FIG. 1A) between adjacent conductive features 106a (or between adjacent conductive features 106b) can be in a range of 0.2 micron to 50 microns, in a range of 0.75 micron to 25 microns, in a range of 1 micron to 25 microns, in a range of 1 micron to 10 microns, or in a range of 1 micron to 5 microns. Further, a major lateral dimension (e.g., a pad diameter) can be small as well, e.g., in a range of 0.1 micron to 30 microns, in a range of 0.25 micron to 5 microns, or in a range of 0.5 micron to 5 microns.

Certain implementations disclosed herein relate to optoelectronic devices that include bonded contacts comprising optically transparent or optically semi-transparent electrically conductive polymer material (referred to herein collectively as conductive polymers or CPs) instead of metal direct bonded contacts. For example, the optoelectronic devices can include optical elements or devices (e.g., photodiodes; light emitting diodes (LEDs)); quantum dot light emitting diodes (QLEDs); lasers; vertical-cavity surface-emitting lasers (VCSELs); transparency control pixels; liquid crystal pixels; adaptive optics; solar cells; waveguides; spatial light modulators; diode lasers; electrochromic devices) that are stacked on or bonded to one another to form a bonded structure. The CPs on separate substrates can be planarized and the planarized surfaces of the substrates can be placed in contact with one another, as described herein, to form the bonded structures.

In certain implementations, the optoelectronic devices described herein are configured to be used in various contexts which are area-limited (e.g., displays for virtual reality (VR) or augmented reality (AR) applications; multijunction solar cells) or other designs comprising an optoelectronic (e.g., electro-optical) element within a stack of other optical elements, beneficially utilizing the CPs for providing electrical connection between electrical elements while not appreciably blocking light.

As used herein, the term “optically transparent” includes but is not limited to optically translucent, optically semi-transparent, and/or having an optical transmittance of at least 50% (e.g., at least 60%; at least 75%; at least 88%; greater than or equal to 95%) at optical wavelengths in a predetermined range. For example, the predetermined range for optically transparent components (e.g., elements; substrates; layers; devices; features) can be visible wavelengths (e.g., 390 nanometers to 750 nanometers; 400 nanometers to 700 nanometers), ultraviolet wavelengths (e.g., 100 nanometers to 400 nanometers), infrared wavelengths (e.g., 800 nanometers to 1 millimeter), and/or short-wave infrared (SWIR) wavelengths (e.g., 1400 nanometers to 3000 nanometers).

It can be challenging in the application of hybrid bonding in optoelectronic devices to reduce (e.g., minimize) the optically opaque contact areas while increasing (e.g., maximizing) the optically transparent areas. Certain implementations described herein utilize electrically conductive polymers (CPs) in place of metal connectors in hybrid bonded devices. Certain such implementations can also include planarization of dielectric surfaces to prepare the CP surfaces for bonding. Upon the surfaces of two substrates being put into contact with one another, the dielectric surface portions can directly bond to one another and the CP surface portions can bond to one another (e.g., without an intervening adhesive material) to form interconnects. For example, the CP surface portions can bond to one another by solvent bonding (e.g., application of a solvent to soften the CP material such that applied pressure results in polymer chain interdiffusion at the bonding junction, which can occur below the glass transition temperature of the CP material), thermal bonding (e.g., heading the CP material to a specific temperature to soften the CP material such that applied pressure and cooling results in bonding upon solidification), and/or mixed interlayer polymer bonding (see, e.g., A. J. Moulé et al., “Mixed interlayers at the interface between PEDOT:PSS and conjugated polymers provide charge transport control,” J. Mater. Chem. C, Vol. 3, pp. 2664-2676 (2015)). In certain implementations, the CP interconnects provide high transparency, low range resistivity (e.g., 10⁻⁴ to 10⁻³ Ω-cm), and/or resilience to mechanical cracking.

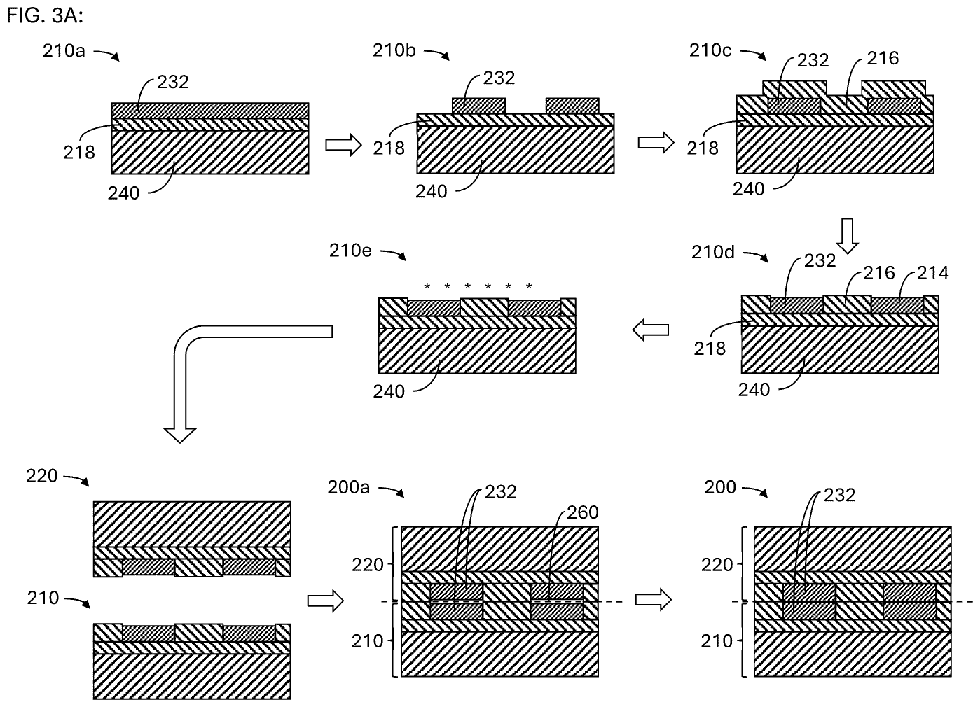

FIGS. 2A and 2B schematically illustrate two cross-sectional views of an example structure 200 in accordance with certain implementations described herein. The structure 200 comprises a first substrate 210 (e.g., first element 102) comprising a first layer 212 having at least one electrically conductive first portion 214 (e.g., conductive feature 106a) and at least one electrically insulative second portion 216. The structure 200 further comprises a second substrate 220 (e.g., second element 104) comprising a second layer 222 having at least one electrically conductive third portion 224 (e.g., conductive feature 106b) and at least one electrically insulative fourth portion 226. The structure 200 further comprises an interface layer 230 between the first layer 212 and the second layer 222 (e.g., formed by bonding of two opposing layers of at least one electrically conductive polymer material 232). The interface layer 230 comprises at least one electrically conductive polymer material 232.

In certain implementations, the first substrate 210 comprises at least one first device 240 and the second substrate 220 comprises at least one second device 250. The at least one first device 240 and/or the at least one second device 250 can be optically transparent (e.g., optoelectronic device; optoelectronic element; electro-optical element; solar cell) or can be optically non-transparent (e.g., opaque). The at least one first device 240 and/or the at least one second device 250 can further comprise electrical conduits (e.g., optically transparent; non-optically transparent). In certain implementations, the first substrate 210 comprises at least one electrical contact (e.g., a large lateral area contact on a backside 116a of the corresponding device portion 110a) in electrical communication with the at least one first device 240 and the second substrate 220 comprises at least one electrical contact (e.g., on a backside 116b of the corresponding device portion 110b) in electrical communication with the at least one second device 250. The electrical contacts can be configured to transmit electrical signals to and/or from the first and/or second devices 240, 250. Example materials for the electrical contacts include but are not limited to copper or copper alloys, although other metals and alloys may be suitable. In addition, the electrical contacts can comprise additional electrically conductive layers between the copper and the corresponding at least one first and/or second device 240, 250. In certain implementations, at least one of the electrical contact comprises an electro-optical (EO) contact comprising a transparent and electrically conductive material (e.g., an electrically conductive polymer material as disclosed herein) that is in electrical and optical communication with the at least one first device 240 and the at least one second device 250, respectively, to transmit electrical and optical signals to and/or from the first and/or second devices 240, 250.

In certain implementations, the first layer 212 is in contact with the first device 240 and/or the second layer 222 is in contact with the second device 250. For example, FIG. 2A schematically illustrates an example structure 200 in which the first layer 212 contacts the first device 240 and the second layer 222 contacts the second device 250. In certain other implementations, the first substrate 210 comprises at least one electrically insulative layer 218 between the first device 240 and the first layer 212 and/or the second substrate 220 comprises at least one electrically insulative layer 228 between the second device 250 and the second layer 222. For example, FIG. 2B schematically illustrates an example structure 200 in which the first substrate 210 comprises an electrically insulative layer 218 and the second substrate 220 comprises an electrically insulative layer 228. Examples of materials for the electrically insulative layers 218, 228 include but are not limited to: semiconductor oxides; semiconductor nitrides; silicon oxide (SiO₂); silicon nitride (SiNₓ, Si₃N₄); silicon oxycarbonitride (SiOₓN_{y}C_{z}); silicon nitride.

In certain implementations, the at least one electrically conductive first portion 214 and/or the at least one electrically conductive third portion 224 comprises at least one electrically conductive material, examples of which include, but are not limited to: copper; tungsten; cobalt; conductive polymer. The conductive polymer can comprise an intrinsically electrically conductive polymer selected from the group consisting of, but not limited to: polyacetylene (PA); polyaniline (PANI); poly[3,4-(ethylenedioxy)thiophene] (PEDOT); PEDOT:polystyrene-sulphonate (PEDOT:PSS); polypyrrole (PPy); polythiophene (PT); poly(o-phenylene-diamine) (PoPDA). In certain implementations, the first and/or third portions 214, 224 are optically transparent, while in certain other implementations, the first and/or third portions 214, 224 are optically non-transparent (e.g., opaque). Each of the first portions 214 and/or the third portions 224 can comprise a single layer or multiple layers. The first and third portions 214, 224 can comprise the same electrically conductive material or can comprise different electrically conductive materials (e.g., materials having different elemental constituents and/or different stoichiometries). The electrically conductive materials of the first and/or third portions 214, 224 can be different from the electrically conductive polymer material 232, and the bonding of the first and/or third portions 214, 224 with the interface layer 230 can comprise hybrid bonding.

In certain implementations, the at least one electrically insulative second portion 216 and/or the at least one electrically insulative fourth portion 226 comprises at least one solid dielectric material (e.g., an inorganic dielectric material), examples of which include, but are not limited to: semiconductor oxides; semiconductor nitrides; silicon oxide (SiO₂); silicon nitride (SiNₓ, Si₃N₄); silicon oxycarbonitride (SiOₓN_{y}C_{z}); silicon nitride. In certain implementations, the second and/or fourth portions 216, 226 are optically transparent, while in certain other implementations, the second and/or fourth portions 216, 226 are optically non-transparent (e.g., opaque). Each of the second portions 216 and/or the fourth portions 226 can comprise a single layer or multiple layers. The second and fourth portions 216, 226 can comprise the same dielectric material or can comprise different dielectric materials (e.g., materials having different elemental constituents and/or different stoichiometries). The dielectric materials of the second and/or fourth portions 216, 226 are different from the electrically conductive polymer material 232, and the bonding of the second and/or fourth portions 216, 226 with the interface layer 230 can comprise hybrid bonding.

In certain implementations, the at least one electrically conductive polymer material 232 comprises an intrinsically electrically conductive polymer selected from the group consisting of, but not limited to: polyacetylene (PA); polyaniline (PANI); poly[3,4-(ethylenedioxy)thiophene] (PEDOT); PEDOT:polystyrene-sulphonate (PEDOT:PSS); polypyrrole (PPy); polythiophene (PT); poly(o-phenylene-diamine) (PoPDA). In certain implementations, the at least one electrically conductive polymer material 232 is optically transparent, while in certain other implementations, the at least one electrically conductive polymer material 232 is optically non-transparent (e.g., opaque). For example, the at least one electrically conductive polymer material 232 can comprise PEDOT or PEDOT:PSS PH1000 (e.g., Baytron® P or Clevois™ available from Heraeus Epurio GmbH of Leverkusen Germany) as an aqueous dispersion of a PEDOT:PSS polyelectrolyte complex, with PSS/PEDOT at a 2.5:1 to 6:1 weight ratio. The at least one electrically conductive polymer material 232 can be doped with small molecules (e.g., LiClO₄) to have a conductivity in a range of 100 S/cm to 1000 S/cm. The at least one electrically conductive polymer material 232 can be moderated by solvents (e.g., methanol; dimethylsulfoxide) and can have a conductivity up to 4600 S/cm. See, e.g., B. J. Worfolk et al., “Ultrahigh electrical conductivity in solution-sheared polymeric transparent films,”PNAS Vol. 112(46), pp. 14138-14143 (2015).

As described herein, the at least one electrically conductive polymer material 232 can comprise a first electrically conductive polymer material 232 on the first layer 212 and a second electrically conductive polymer material 232 on the second layer 222, and the interface layer 230 can be formed by bonding the first electrically conductive polymer material 232 to the second electrically conductive polymer material 232. In certain implementations, the interface layer 230 has a thickness in a range of 5 nm to 3 microns. In certain implementations, the resistivity of the electrically conductive polymer is in a range of 1×10⁻⁴ Ω-cm to 2.5 Ω-cm (e.g., 1.1×10⁻Ω-cm to 1×10⁻¹ Ω-cm; 1.3×10⁻⁴ Ω-cm to 1×10⁻¹ Ω-cm; in a range of 1.6×10⁻⁴ Ω-cm to 3.3×10⁻² Ω-cm; in a range of 2.2×10⁻⁴ Ω-cm to 5×10⁻³ Ω-cm). In certain implementations, the optical transmission within the wavelength range of interest is greater than 40% (e.g., greater than 60%; greater than 80%).

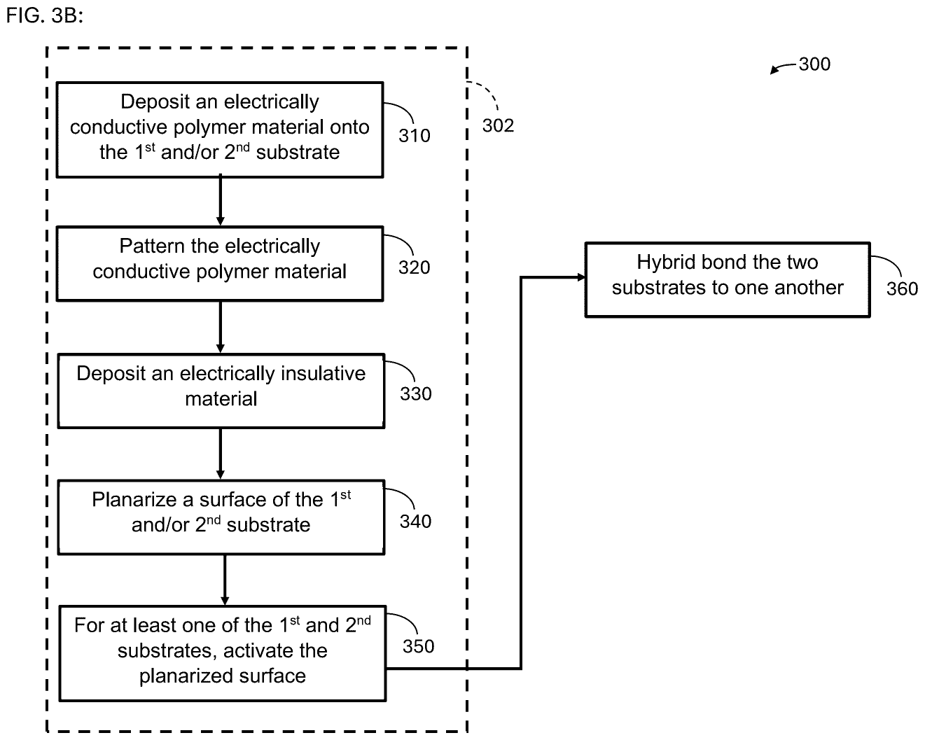

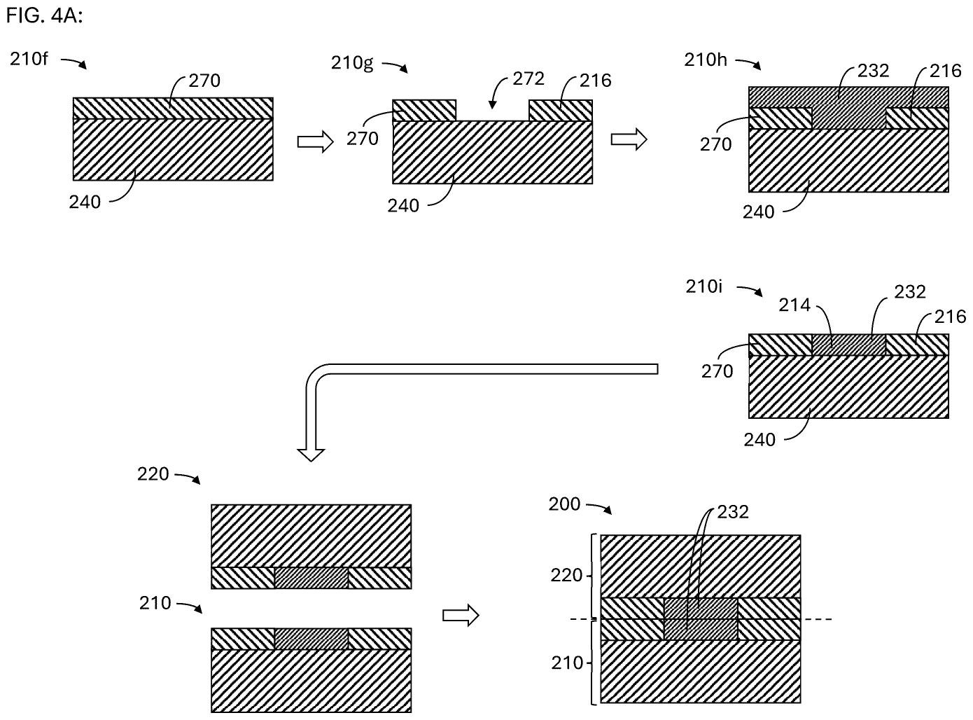

FIG. 3A schematically illustrates various example intermediate structures 210a-210e for the first substrate 210 obtained during an example method 300 for fabricating an example structure 200 in accordance with certain implementations described herein. FIG. 3B is a flow diagram of the example method 300 for forming the example structure 200 in accordance with certain implementations described herein. While FIG. 3A schematically illustrates the intermediate structures 210a-210e corresponding to providing the first substrate 210, providing the second substrate 220 can also be performed in a similar manner, resulting in similar intermediate structures of the second substrate 220 as those shown in FIG. 3A.

In an operational block 302, the method 300 comprises providing the first substrate 210 (e.g., first element 102) and the second substrate 220 (e.g., second element 104). Each of the first and second substrates 210, 220 can comprise one or more electrically conductive surface portions (e.g., the first substrate 210 comprising first portions 214 or conductive features 106a; the second substrate 220 comprising third portions 224 or conductive features 106b) and one or more electrically insulative surface portions (e.g., the first substrate 210 comprising second portions 216; the second substrate 220 comprising fourth portions 226). The one or more electrically conductive surface portions of at least one of the first substrate 210 and the second substrate 220 comprise an electrically conductive polymer material 232.

In certain implementations, the first substrate 210 and/or the second substrate 220 comprises at least one dielectric layer (e.g., the at least one electrically insulative layer 218, 228; silicon oxide; silicon nitride; silicon carbide; an undoped semiconductor material, such as undoped silicon). For example, the at least one dielectric layer can be deposited onto the first device 240 to have a thickness in a range of 0.1 micron to 1 micron (e.g., 0.5 micron). While FIG. 3A schematically illustrates the first substrate 210 as including the at least one electrically insulative layer 218 over the first device 240, in certain other implementations, the first substrate 210 and/or the second substrate 220 can be provided without the at least one electrically insulative layer 218, 228.

In an operational block 310, providing the first and second substrates 210, 220 comprises depositing an electrically conductive polymer material 232 onto the first substrate 210 and/or the second substrate 220. For example, the electrically conductive polymer material 232 can be deposited to have a thickness in a range of 0.5 micron to 5 microns (e.g., 2 microns) in multiple cycles that each include spin coating a sublayer of the electrically conductive polymer material 232, the sublayer having a thickness in a range of 30 nm to 1200 nm (e.g., 60 nm to 800 nm). Each cycle can further include annealing the sublayer (e.g., using infrared lamps or heating plate) at a temperature in a range of 90° C. to 130° C. (e.g., 100° C. to 110° C.) for an annealing time in a range of 0.5 minute to 10 minutes (e.g., 1 minute to 5 minutes). The resulting structure is schematically illustrated by FIG. 3A as intermediate structure 210a.

In an operational block 320, providing the first and second substrates 210, 220 further comprises patterning the electrically conductive surface portions (e.g., the electrically conductive polymer material 232) to electrically isolate at least two regions of the electrically conductive surface portions on the first substrate 210 from one another and/or to electrically isolate at least two regions of the electrically conductive surface portions on the second substrate 220 from one another. For example, the patterning can be performed using positive resist patterning and dry etching. The resulting structure is schematically illustrated by FIG. 3A as intermediate structure 210b.

In an operational block 330, providing the first and second substrates 210, 220 further comprises depositing an electrically insulative material (e.g., the material of the at least one electrically insulative second and/or fourth portions 216, 226) over the electrically conductive surface portions. For example, a dielectric material can be deposited (e.g., via sputtering, activated chemical vapor deposition (CVD), directional physical vapor deposition (PVD), or atomic layer deposition (ALD) to a thickness on the order of microns) over the patterned electrically conductive polymer material 232 at a temperature below 100° C. The resulting structure is schematically illustrated by FIG. 3A as intermediate structure 210c.

In an operational block 340, providing the first and second substrates 210, 220 further comprises planarizing (e.g., using chemical mechanical polishing (CMP)) a surface of the first substrate 210 and/or the second substrate 220, the surface comprising the electrically conductive surface portions (e.g., the electrically conductive polymer material 232). The resulting structure is schematically illustrated by FIG. 3A as intermediate structure 210d.

In an operational block 350, providing the first and second substrates 210, 220 further comprises, for at least one of the first substrate 210 and the second substrate 220, activating the planarized surface of the first substrate 210 and/or the second substrate 220 (e.g., exposing the planarized surface to plasma and/or chemical etchants). The activation can be performed prior to hybrid bonding the first substrate 210 and the second substrate 220 with one another. The resulting structure is schematically illustrated by FIG. 3A as intermediate structure 210e.

In an operational block 360, the method 300 further comprises hybrid bonding the first substrate 210 and the second substrate 220 to one another without an intervening adhesive. The hybrid bonding comprises contacting the one or more electrically conductive surface portions 214 of the first substrate 210 with the one or more electrically conductive surface portions 224 of the second substrate 220 and contacting the one or more electrically insulative surface portions 216 of the first substrate 210 with the one or more electrically insulative surface portions 226 of the second substrate 220.

For example, if the electrically conductive surface portions 214 (e.g., the electrically conductive polymer material 232) on the first substrate 210 and the electrically conductive surface portions 224 on the second substrate 220 are substantially flush with or protrude relative to the exterior (e.g., upper) surfaces of the electrically insulative surface portions 216, 226, the electrically conductive surface portions 214, 224 can be contacted with one another and the electrically insulative surface portions 216, 226 can be contacted with one another, such that the electrically insulative surface portions 26, 226 directly bond with one another and the electrically conductive surface portions 214, 224 bond with one another.

For another example, if the respective electrically conductive surface portions 214, 224 are recessed below the exterior surfaces of the electrically insulative surface portions 216, 226, hybrid bonding the first substrate 210 and the second substrate 220 to one another comprises contacting the electrically insulative surface portions 216, 226 with one another, leaving gaps 260 between opposing electrically conductive surface portions 214, 224 of less than 15 nm (e.g., less than 10 nm), and directly bonding the electrically insulative surface portions 216, 226 to one another. The resulting structure is schematically illustrated by FIG. 3A as intermediate structure 200a. In certain such implementations, the intermediate structure 220a can be annealed at a temperature higher than the room temperature (e.g., heating the intermediate structure 200a at a temperature in a range of 90° C. to 200° C., such as 110° C. for an annealing time in a range of 10 minutes to 60 minutes) to cause the conductive polymer material 232 to expand to close the gap 260 to contact one another, and to bond the electrically conductive surface portions 214, 224 to one another. For example, under such annealing conditions, a 2-micron-thick layer of conductive polymer material 232 can expand by about 10 nm. The annealing ambient can comprise at least one of: nitrogen, forming gas, hydrogen plasma, vacuum, or other predetermined ambient. The annealing chamber can comprise one or more ovens (e.g., rapid thermal anneal (RTA) ovens; microwave ovens; ovens for processing semiconductor wafers, flat panels, etc.). The resulting structure 200 is schematically illustrated by FIG. 3A.

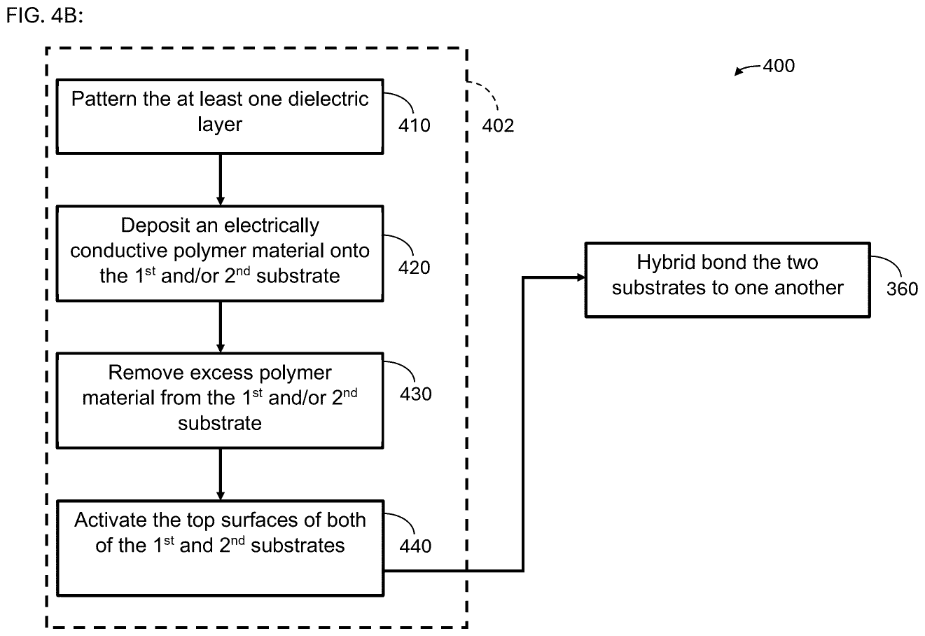

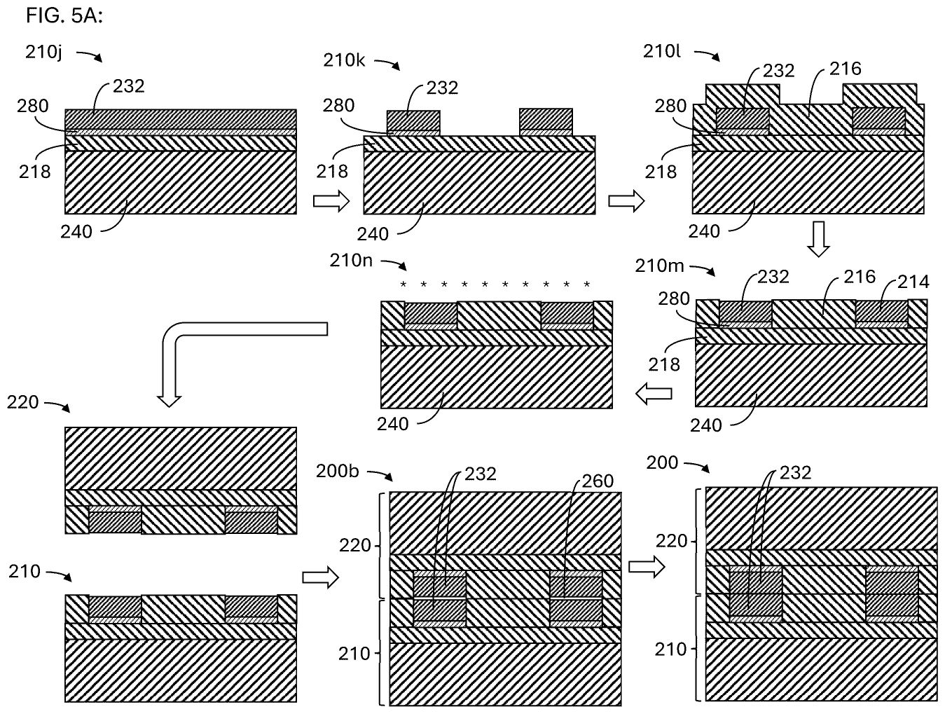

FIG. 4A schematically illustrates various example intermediate structures 210f-210i for the first substrate 210 obtained during another example method 400 for fabricating an example structure 200 in accordance with certain implementations described herein. FIG. 4B is a flow diagram of the example method 400 for forming the example structure 200 in accordance with certain implementations described herein. While FIG. 4A schematically illustrates the intermediate structures 210f-210i corresponding to providing the first substrate 210, providing the second substrate 220 can also be performed in a similar manner, resulting in similar intermediate structures of the second substrate 220 as those shown in FIG. 4A.

In an operational block 402, the method 400 comprises providing the first substrate 210 (e.g., first element 102) and the second substrate 220 (e.g., second element 104). Each of the first and second substrates 210, 220 can comprise one or more electrically conductive surface portions (e.g., the first substrate 210 comprising first portions 214 or conductive features 106a; the second substrate 220 comprising third portions 224 or conductive features 106b) and one or more electrically insulative surface portions (e.g., the first substrate 210 comprising second portions 216; the second substrate 220 comprising fourth portions 226). The one or more electrically conductive surface portions of at least one of the first substrate 210 and the second substrate 220 comprise an electrically conductive polymer material 232.

In certain implementations, the first substrate 210 and/or the second substrate 220 comprises at least one dielectric layer 270 (e.g., silicon oxide; silicon nitride; silicon carbide; an undoped semiconductor material, such as undoped silicon) at a top surface of the first substrate 210. For example, the at least one dielectric layer 270 can be deposited onto the first device 240 to have a thickness in a range of 0.5 micron to 5 microns (e.g., 2 microns) and can be planarized (e.g., using CMP).

In an operational block 410, providing the first and second substrates 210, 220 comprises patterning the at least one dielectric layer 270 (e.g., using positive resist patterning and dry etching). The patterning can form recesses 272 within the at least one dielectric layer 270, the recesses 272 electrically isolating at least two regions of the at least one dielectric layer 270 from one another. The isolated regions can be the at least one electrically insulative second portions 216 of the first substrate 210 and/or fourth portions 226 of the second substrate 220. The resulting structure is schematically illustrated by FIG. 4A as intermediate structure 210g.

In an operational block 420, providing the first and second substrates 210, 220 further comprises depositing an electrically conductive polymer material 232 onto the patterned at least one dielectric layer 270 of the first substrate 210 and/or the second substrate 220. For example, the electrically conductive polymer material 232 can be deposited to fill the recesses 272 and to cover the isolated regions of the at least one dielectric layer 270 (e.g., the second and/or fourth portions 216, 226). The electrically conductive surface portions 214 of the first substrate 210 comprise the electrically conductive polymer material 232 that fill the recesses 272 between the isolated regions of the at least one dielectric layer 270. The electrically conductive polymer material 232 on the isolated regions of the at least one dielectric layer 270 (e.g., the second and/or fourth portions 216, 226) can have a thickness in a range of 0.5 micron to 5 microns (e.g., 2 microns), deposited in multiple cycles that each include spin coating a sublayer of the electrically conductive polymer material 232, the sublayer having a thickness in a range of 30 nm to 1200 nm (e.g., 60 nm to 800 nm). Each cycle can further include annealing the sublayer (e.g., using infrared lamps or heating plate) at a temperature in a range of 90° C. to 130° C. (e.g., 100° C. to 110° C.) for an annealing time in a range of 0.5 minute to 10 minutes (e.g., 1 minute to 5 minutes). The resulting structure is schematically illustrated by FIG. 4A as intermediate structure 210h.

In an operational block 430, providing the first and second substrates 210, 220 further comprises removing excess conductive polymer material 232 from the top surface of the first substrate 210. For the first substrate 210, removing the excess conductive polymer material 232 electrically isolates at least two regions of the electrically conductive surface portions 214 on the first substrate 210 from one another, and for the second substrate 220, removing the excess conductive polymer material 232 electrically isolates at least two regions of the electrically conductive surface portions 224 on the second substrate 220 from one another. For example, the excess conductive polymer material 232 can be removed using CMP or using liftoff (e.g., removing a deposited sacrificial photoresist layer via a chemical etch). As shown in FIG. 4A, the remaining conductive polymer material 232 is embedded within the at least one electrically insulative second and/or fourth portions 216, 226. In certain implementations, as a result of removing the excess conductive polymer material 232, the outer top surface of the remaining conductive polymer material 232 within the recesses 272 is lower than (e.g., recessed below) the outer top surface of the at least one electrically insulative surface portions 216 (e.g., by less than 15 nm; by less than 10 nm). The resulting structure is schematically illustrated by FIG. 4A as intermediate structure 210i.

In an operational block 440, providing the first and second substrates 210, 220 further comprises, activating the outer top surface of the first substrate 210 and the outer top surface of the second substrate 220 (e.g., exposing the outer top surfaces to plasma and/or chemical etchants). The activation can be performed prior to hybrid bonding the first substrate 210 and the second substrate 220 with one another.

In an operational block 360, the method 400 further comprises hybrid bonding the first substrate 210 and the second substrate 220 to one another without an intervening adhesive. The hybrid bonding comprises contacting the one or more electrically conductive surface portions 214 of the first substrate 210 with the one or more electrically conductive surface portions 224 of the second substrate 220 and contacting the one or more electrically insulative surface portions 216 of the first substrate 210 with the one or more electrically insulative surface portions 226 of the second substrate 220. In certain implementations, the hybrid bonding of the method 400 is performed as described herein with regard to the hybrid bonding of the method 300. In addition, the method 400 can further comprise annealing the first and second substrates 210, 220 as described herein with regard to the hybrid bonding of the method 300. The resulting structure 200 is schematically illustrated by FIG. 4A.

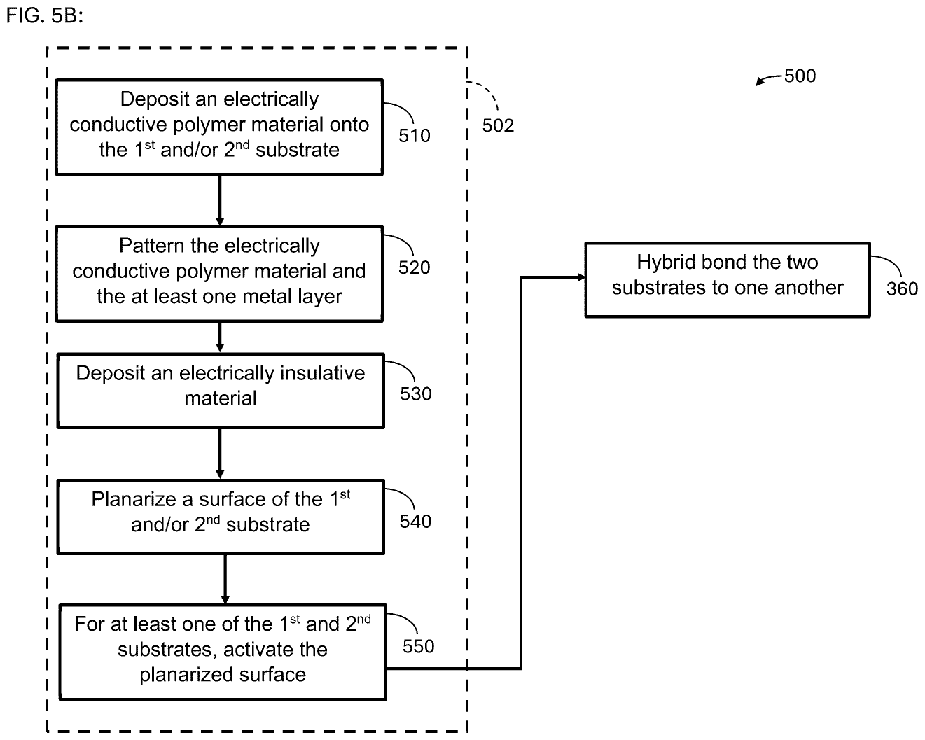

FIG. 5A schematically illustrates various example intermediate structures 210j-210n for the first substrate 210 obtained during another example method 500 for fabricating an example structure 200 in accordance with certain implementations described herein. FIG. 5B is a flow diagram of the example method 500 for forming the example structure 200 in accordance with certain implementations described herein. While FIG. 5A schematically illustrates the intermediate structures 210j-210n corresponding to providing the first substrate 210, providing the second substrate 220 can also be performed in a similar manner, resulting in similar intermediate structures of the second substrate 220 as those shown in FIG. 5A.

In an operational block 502, the method 500 comprises providing the first substrate 210 (e.g., first element 102) and the second substrate 220 (e.g., second element 104). Each of the first and second substrates 210, 220 can comprise one or more electrically conductive surface portions (e.g., the first substrate 210 comprising first portions 214 or conductive features 106a; the second substrate 220 comprising third portions 224 or conductive features 106b) and one or more electrically insulative surface portions (e.g., the first substrate 210 comprising second portions 216; the second substrate 220 comprising fourth portions 226). The one or more electrically conductive surface portions of at least one of the first substrate 210 and the second substrate 220 comprise an electrically conductive polymer material 232.

In certain implementations, the first substrate 210 and/or the second substrate 220 comprises at least one dielectric layer (e.g., the at least one electrically insulative layer 218, 228; silicon oxide; silicon nitride; silicon carbide; an undoped semiconductor material, such as undoped silicon). For example, the at least one dielectric layer can be deposited onto the first device 240 to have a thickness in a range of 0.1 micron to 1 micron (e.g., 0.5 micron). While FIG. 5A schematically illustrates the first substrate 210 as including the at least one electrically insulative layer 218 over the first device 240, in certain other implementations, the first substrate 210 and/or the second substrate 220 can be provided without the at least one electrically insulative layer 218, 228.

In an operational block 510, providing the first and second substrates 210, 220 comprises depositing an electrically conductive polymer material 232 onto the first substrate 210 and/or the second substrate 220. For example, the electrically conductive polymer material 232 can be deposited using electrochemical deposition which comprises depositing a metal layer 280 (e.g., NiV; Cu) over the at least one electrically insulative layer 218, 228 (e.g., using PVD), the metal layer 280 having a thickness in a range of 10 nm to 100 nm (e.g., 50 nm), and using electrochemical deposition to deposit the electrically conductive polymer material 232 over the metal layer 280. The deposited electrically conductive polymer material 232 can have a thickness in a range of 0.5 micron to 5 microns (e.g., 1 micron) and the electrically conductive polymer material 232 can be annealed (e.g., using infrared lamps or heating plate) at a temperature in a range of 90° C. to 130° C. (e.g., 100° C. to 110° C.) for an annealing time in a range of 0.5 minute to 10 minutes (e.g., 1 minute to 5 minutes). The resulting structure is schematically illustrated by FIG. 5A as intermediate structure 210j.

In an operational block 520, providing the first and second substrates 210, 220 further comprises patterning the electrically conductive surface portions (e.g., the electrically conductive polymer material 232 and the metal layer 280) to electrically isolate at least two regions of the electrically conductive surface portions on the first substrate 210 from one another and/or to electrically isolate at least two regions of the electrically conductive surface portions on the second substrate 220 from one another. For example, the patterning can be performed using positive resist patterning and dry etching. The resulting structure is schematically illustrated by FIG. 5A as intermediate structure 210k.

In an operational block 530, providing the first and second substrates 210, 220 further comprises depositing an electrically insulative material (e.g., the material of the at least one electrically insulative second and/or fourth portions 216, 226) over the electrically conductive surface portions. For example, a dielectric material can be deposited (e.g., via sputtering, activated CVD, directional PVD, or ALD to a thickness on the order of microns) over the patterned electrically conductive polymer material 232 and metal layer 280 at a temperature below 100° C. The resulting structure is schematically illustrated by FIG. 5A as intermediate structure 2101.

In an operational block 540, providing the first and second substrates 210, 220 further comprises planarizing (e.g., using chemical mechanical polishing (CMP)) a surface of the first substrate 210 and/or the second substrate 220, the surface comprising the electrically conductive surface portions (e.g., the electrically conductive polymer material 232 and the metal layer 280). The resulting structure is schematically illustrated by FIG. 5A as intermediate structure 210m.

In an operational block 550, providing the first and second substrates 210, 220 further comprises, for at least one of the first substrate 210 and the second substrate 220, activating the planarized surface of the first substrate 210 and/or the second substrate 220 (e.g., exposing the planarized surface to plasma and/or chemical etchants). The activation can be performed prior to hybrid bonding the first substrate 210 and the second substrate 220 with one another. The resulting structure is schematically illustrated by FIG. 5A as intermediate structure 210n.

In an operational block 360, the method 500 further comprises hybrid bonding the first substrate 210 and the second substrate 220 to one another without an intervening adhesive. The hybrid bonding comprises contacting the one or more electrically conductive surface portions 214 of the first substrate 210 with the one or more electrically conductive surface portions 224 of the second substrate 220 and contacting the one or more electrically insulative surface portions 216 of the first substrate 210 with the one or more electrically insulative surface portions 226 of the second substrate 220. In certain implementations, the hybrid bonding of the method 500 is performed as described herein with regard to the hybrid bonding of the method 300. In addition, the outer top surfaces of the conductive polymer material 232 can be recessed (e.g., by less than 15 nm; by less than 10 nm) relative to the electrically insulative surface portions 216, 226, and the method 500 can further comprise annealing the first and second substrates 210, 220 as described herein with regard to the hybrid bonding of the method 300 to close the gaps 260 of intermediate structure 200b of FIG. 5A. The resulting structure 200 is schematically illustrated by FIG. 5A.

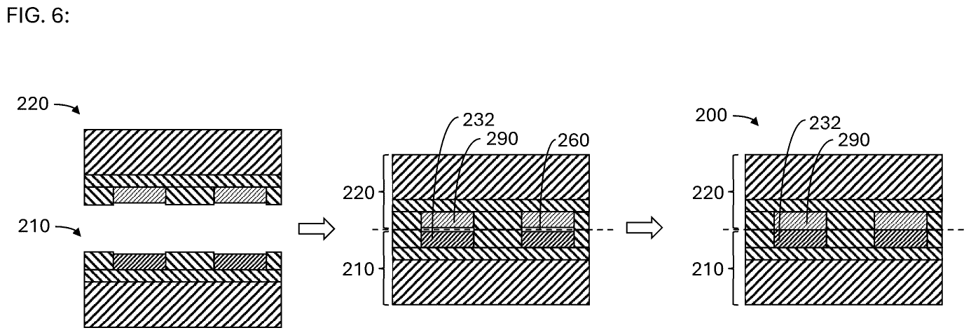

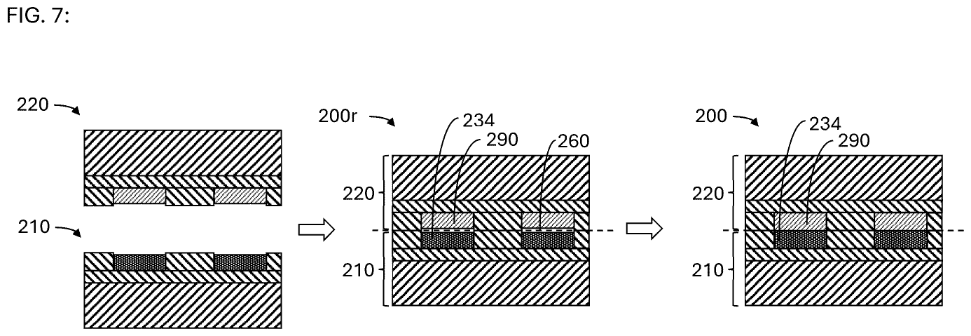

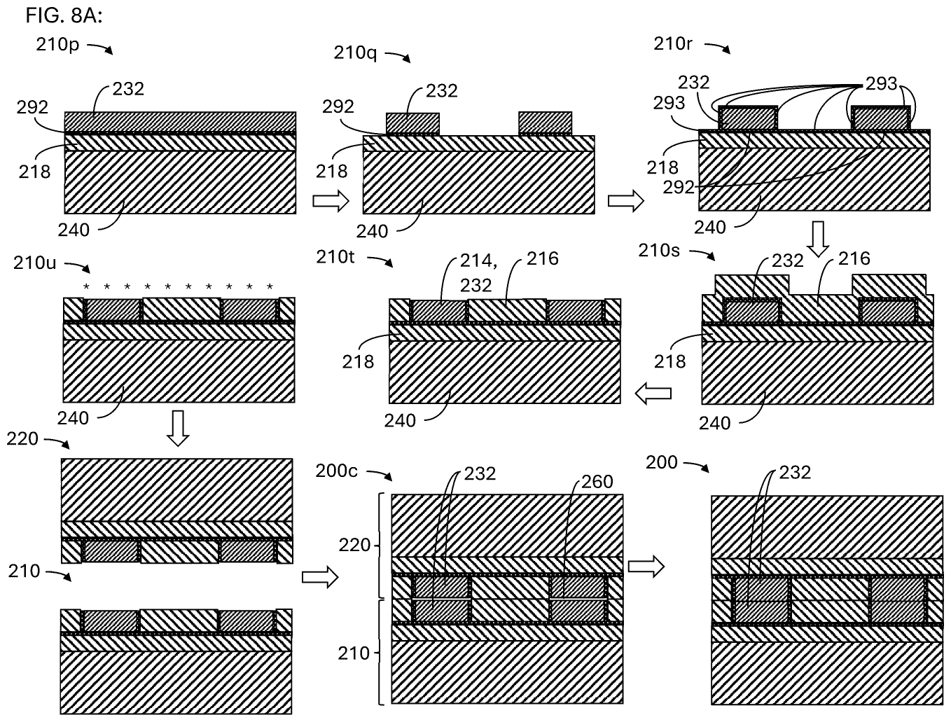

As described herein with regard to FIGS. 3A, 4A, and 5A, in certain implementations, both the electrically conductive surface portions 214 of the first substrate 210 and the electrically conductive surface portions 224 of the second substrate 220 comprise an electrically conductive polymer material 232. In certain implementations, the electrically conductive surface portions 214 of the first substrate 210 comprise an electrically conductive polymer material 232 and the electrically conductive surface portions 224 of the second substrate 220 do not comprise the electrically conductive polymer material 232. For example, each of FIGS. 6 and 7 schematically illustrates the electrically conductive surface portions 214 of the second substrate 220 comprising an electrically conductive metal material 290 (e.g., Cu; Al; Cu alloy; Al alloy) in accordance with certain implementations described herein. In FIG. 6, the electrically conductive surface portions 214 of the first substrate 210 comprise an electrically conductive polymer material 232. In FIG. 7, the electrically conductive surface portions 214 of the first substrate 210 comprise a hybrid conductive polymer (HCP) material 234 comprising a mixture of an electrically conductive polymer material with an inorganic compound (e.g., oxides), with at least one of the electrically conductive polymer material and the inorganic compound in nanoparticle form. As shown in FIGS. 6 and 7, the outer top surfaces of the electrically conductive surface portions 214 and/or the metal material 290 can be recessed (e.g., by less than 15 nm; by less than 10 nm) relative to the electrically insulative surface portions 216, 226, and annealing the first and second substrates 210, 220 as described herein with regard to the hybrid bonding of the method 300 can cause the electrically conductive surface portions 214 and/or the metal material 290 to expand and bond to one another, thereby closing the gaps 260, as shown in FIGS. 6 and 7.

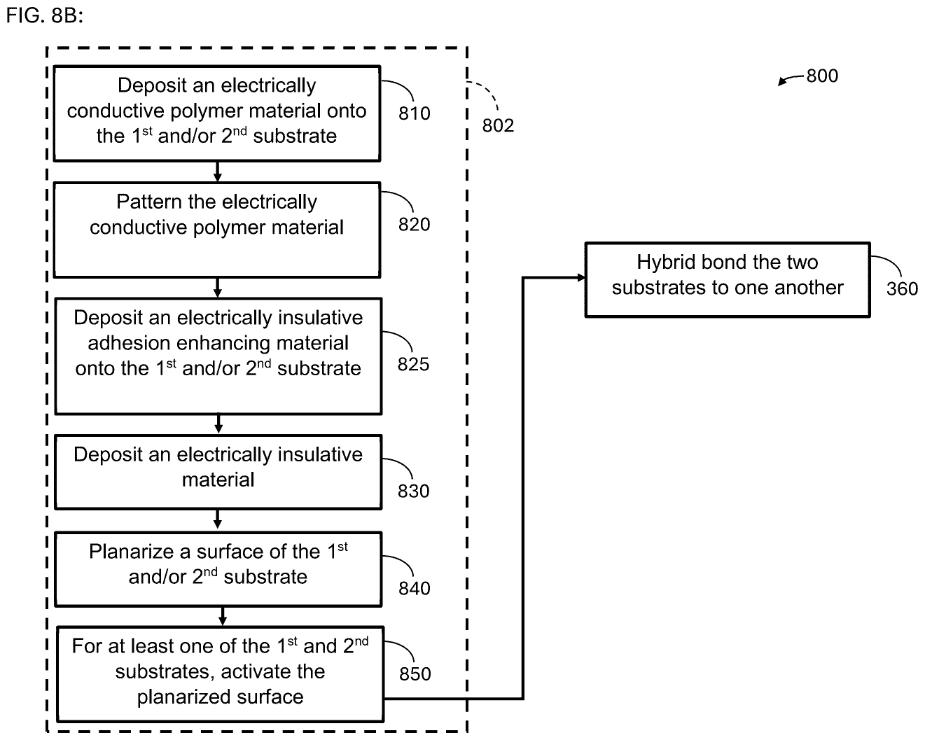

FIG. 8A schematically illustrates various example intermediate structures 210p-210u for the first substrate 210 obtained during another example method 800 for fabricating an example structure 200 in accordance with certain implementations described herein. FIG. 8B is a flow diagram of the example method 800 for forming the example structure 200 in accordance with certain implementations described herein. While FIG. 8A schematically illustrates the intermediate structures 210p-210u corresponding to providing the first substrate 210, providing the second substrate 220 can also be performed in a similar manner, resulting in similar intermediate structures of the second substrate 220 as those shown in FIG. 8A.

In an operational block 802, the method 800 comprises providing the first substrate 210 (e.g., first element 102) and the second substrate 220 (e.g., second element 104). Each of the first and second substrates 210, 220 can comprise one or more electrically conductive surface portions (e.g., the first substrate 210 comprising first portions 214 or conductive features 106a; the second substrate 220 comprising third portions 224 or conductive features 106b) and one or more electrically insulative surface portions (e.g., the first substrate 210 comprising second portions 216; the second substrate 220 comprising fourth portions 226). The one or more electrically conductive surface portions of at least one of the first substrate 210 and the second substrate 220 comprise an electrically conductive polymer material 232.

In certain implementations, the first substrate 210 and/or the second substrate 220 comprises at least one dielectric layer (e.g., the at least one electrically insulative layer 218, 228; silicon oxide; silicon nitride; silicon carbide; an undoped semiconductor material, such as undoped silicon) and at least one electrically conductive adhesion enhancing material 292 (e.g., primer; conductive polydopamine or PDA) on the at least one dielectric material. For example, the at least one dielectric layer can be deposited onto the first device 240 to have a thickness in a range of 0.1 micron to 1 micron (e.g., 0.5 micron) and can be planarized (e.g., using CMP) and. While FIG. 8A schematically illustrates the first substrate 210 as including the at least one electrically insulative layer 218 over the first device 240 and the at least one electrically conductive adhesion enhancing material 292 over the at least one dielectric layer, in certain other implementations, the first substrate 210 and/or the second substrate 220 can be provided without the at least one electrically insulative layer 218, 228 and the method 800 can comprise depositing the at least one dielectric material on the first substrate 210 and/or the second substrate 220 and depositing the at least one electrically conductive adhesion enhancing material 292 onto the at least one dielectric material. The at least one electrically conductive adhesion enhancing material 292 of certain implementations can be considered to be an organic conductive seed layer that enhances adhesion and enables growth of a conductive polymer on the surface.

In an operational block 810, providing the first and second substrates 210, 220 comprises depositing an electrically conductive polymer material 232 onto the first substrate 210 and/or the second substrate 220. For example, the electrically conductive polymer material 232 can be deposited onto the at least one electrically conductive adhesion enhancing material 292 to have a thickness in a range of 0.5 micron to 5 microns (e.g., 2 microns) in multiple cycles that each include spin coating a sublayer of the electrically conductive polymer material 232, the sublayer having a thickness in a range of 30 nm to 1200 nm (e.g., 60 nm to 800 nm). Each cycle can further include annealing the sublayer (e.g., using infrared lamps or heating plate) at a temperature in a range of 90° C. to 130° C. (e.g., 100° C. to 110° C.) for an annealing time in a range of 0.5 minute to 10 minutes (e.g., 1 minute to 5 minutes). The resulting structure is schematically illustrated by FIG. 8A as intermediate structure 210p.

In an operational block 820, providing the first and second substrates 210, 220 further comprises patterning the electrically conductive surface portions (e.g., the electrically conductive polymer material 232 and the at least one electrically conductive adhesion enhancing material 292) to electrically isolate at least two regions of the electrically conductive surface portions on the first substrate 210 from one another and/or to electrically isolate at least two regions of the electrically conductive surface portions on the second substrate 220 from one another. For example, the patterning can be performed using positive resist patterning and dry etching. The resulting structure is schematically illustrated by FIG. 8A as intermediate structure 210q.

In an operational block 825, providing the first and second substrates 210, 220 further comprises depositing at least one electrically insulative adhesion enhancing material 293 (e.g., primer; insulating polydopamine or PDA) onto the electrically conductive polymer material 232 and onto the exposed portions of the at least one dielectric material. The at least one electrically conductive adhesion enhancing material 292 is between the electrically insulative layer 218 and the patterned electrically conductive polymer material 232 and the electrically insulative adhesion enhancing material 293 is on the top and side surfaces of the patterned electrically conductive polymer material 232 and on top of the electrically insulative layer 218. The resulting structure is schematically illustrated by FIG. 8A as intermediate structure 210r.

In an operational block 830, providing the first and second substrates 210, 220 further comprises depositing an electrically insulative material (e.g., the material of the at least one electrically insulative second and/or fourth portions 216, 226) over the electrically conductive surface portions covered by the electrically insulative adhesion enhancing material 293. For example, a dielectric material can be deposited over the electrically insulative adhesion enhancing material 293 that covers the patterned electrically conductive polymer material 232 at a temperature below 100° C. The resulting structure is schematically illustrated by FIG. 8A as intermediate structure 210s.

In an operational block 840, providing the first and second substrates 210, 220 further comprises planarizing (e.g., using chemical mechanical polishing (CMP)) a surface of the first substrate 210 and/or the second substrate 220, the surface comprising the electrically conductive surface portions (e.g., the electrically conductive polymer material 232). The resulting structure is schematically illustrated by FIG. 8A as intermediate structure 210t.

In an operational block 850, providing the first and second substrates 210, 220 further comprises, for at least one of the first substrate 210 and the second substrate 220, activating the planarized surface of the first substrate 210 and/or the second substrate 220 (e.g., exposing the planarized surface to plasma and/or chemical etchants). The activation can be performed prior to hybrid bonding the first substrate 210 and the second substrate 220 with one another. The resulting structure is schematically illustrated by FIG. 8A as intermediate structure 210u.

In an operational block 360, the method 800 further comprises hybrid bonding the first substrate 210 and the second substrate 220 to one another without an intervening adhesive. The hybrid bonding comprises contacting the one or more electrically conductive surface portions 214 of the first substrate 210 with the one or more electrically conductive surface portions 224 of the second substrate 220 and contacting the one or more electrically insulative surface portions 216 of the first substrate 210 with the one or more electrically insulative surface portions 226 of the second substrate 220. In certain implementations, the hybrid bonding of the method 800 is performed as described herein with regard to the hybrid bonding of the method 300. In addition, the method 800 can further comprise annealing the first and second substrates 210, 220 as described herein with regard to the hybrid bonding of the method 300, to close the gaps 260 of intermediate structure 200c of FIG. 8A. The resulting structure 200 is schematically illustrated by FIG. 8A.

In certain implementations, the bonded structures 200 can be coated with a protective layer, mounted on a dicing sheet, and singulated (e.g., by saw dicing, laser dicing, reactive ion etch dicing, wet etching, or a combination thereof) to form singulated dies on the dicing frame. The protective layer can be removed (e.g., stripped) from the singulated dies and the exposed dicing sheet (e.g., using solvent, reactive ion etching, etc.). The singulated die can be cleaned (e.g., rinsed and dried using spin drying or other processes). The cleaned dies can be configured for subsequent processes. For example, a cleaned die can be further bonded to a prepared surface of another substrate (e.g., comprising a power pad, ground pads, and/or other passive elements configured to transmit power to the bonded die).

Although commonly used terms are used to describe the systems and methods of certain implementations for ease of understanding, these terms are used herein to be interpreted fairly. Although various aspects of the disclosure are described with regard to illustrative examples and implementations, the disclosed examples and implementations should not be construed as limiting. Conditional language, such as, among others, “can,” “could,” “might,” or “may,” unless specifically stated otherwise, or otherwise understood within the context as used, is generally intended to convey that certain implementations include, while other implementations do not include, certain features, elements and/or steps. Thus, such conditional language is not generally intended to imply that features, elements and/or steps are in any way required for one or more implementations or that one or more implementations necessarily include logic for deciding, with or without user input or prompting, whether these features, elements and/or steps are included or are to be performed in any particular implementation. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

It is to be appreciated that the implementations disclosed herein are not mutually exclusive and may be combined with one another in various arrangements. In addition, although the disclosed methods and apparatuses have largely been described in the context of direct bonding processes, various implementations described herein can be incorporated in a variety of other suitable devices, methods, and contexts.

Language of degree, as used herein, such as the terms “approximately,” “about,” “generally,” and “substantially,” represent a value, amount, or characteristic close to the stated value, amount, or characteristic that still performs a desired function or achieves a desired result. For example, the terms “approximately,” “about,” “generally,” and “substantially” may refer to an amount that is within ±10% of, within ±5% of, within ±2% of, within ±1% of, or within ±0.1% of the stated amount. As another example, the terms “generally parallel” and “substantially parallel” refer to a value, amount, or characteristic that departs from exactly parallel by ±10 degrees, by +5 degrees, by ±2 degrees, by ±1 degree, or by ±0.1 degree, and the terms “generally perpendicular” and “substantially perpendicular” refer to a value, amount, or characteristic that departs from exactly perpendicular by ±10 degrees, by ±5 degrees, by ±2 degrees, by ±1 degree, or by ±0.1 degree. The ranges disclosed herein also encompass any and all overlap, sub-ranges, and combinations thereof. Language such as “up to,” “at least,” “greater than,” less than,” “between,” and the like includes the number recited. As used herein, the meaning of “a,” “an,” and “said” includes plural reference unless the context clearly dictates otherwise. Also, as used in the description herein, the meaning of “in” includes “into” and “on,” unless the context clearly dictates otherwise.

While the methods and systems are discussed herein in terms of elements labeled by ordinal adjectives (e.g., first, second, etc.), the ordinal adjective are used merely as labels to distinguish one element from another (e.g., one substrate from another or one surface layer from one another), and the ordinal adjective is not used to denote an order of these elements or of their use.

The disclosure described and claimed herein is not to be limited in scope by the specific example implementations herein disclosed, since these implementations are intended as illustrations, and not limitations, of several aspects of the disclosure. Any equivalent implementations are intended to be within the scope of this disclosure. Indeed, various modifications of the disclosure in form and detail, in addition to those shown and described herein, will become apparent to those skilled in the art from the foregoing description. Such modifications are also intended to fall within the scope of the claims. The breadth and scope of the disclosure should not be limited by any of the example implementations disclosed herein, but should be defined only in accordance with the claims and their equivalents.

1. A structure comprising:
a first substrate comprising a first layer having at least one electrically conductive first portion and at least one electrically insulative second portion;
a second substrate comprising a second layer having at least one electrically conductive third portion and at least one electrically insulative fourth portion; and
an interface region between the first layer and the second layer, the interface region comprising at least one electrically conductive polymer material.

2. The structure of claim 1, wherein the at least one electrically conductive polymer material is optically transparent.

3. The structure of claim 1, wherein the at least one electrically conductive first portion comprises a first electrically conductive polymer material and the at least one electrically conductive third portion comprises a second electrically conductive polymer material, the first electrically conductive polymer material bonded to the second electrically conductive polymer material.

4. The structure of claim 1, wherein the at least one electrically conductive first portion comprises a first electrically conductive polymer material and the at least one electrically conductive third portion comprises an electrically conductive metal material, the first electrically conductive polymer material bonded to the electrically conductive metal material.

5. (canceled)

6. The structure of claim 1, wherein the at least one electrically insulative second portion and/or the at least one electrically insulative fourth portion comprises at least one solid dielectric material selected from the group consisting of: silicon oxide, silicon oxycarbonitride, silicon nitride.

7. The structure of claim 1, wherein the at least one electrically conductive polymer material is embedded within the at least one electrically insulative second portion and/or the at least one electrically insulative fourth portion.

8. A structure comprising:
a first substrate having a first conductive feature comprising a first deposited electrically conductive polymer material; and
a second substrate having a second conductive feature, the second substrate hybrid bonded to the first substrate such that the second conductive feature is bonded to the first conductive feature.

9. The structure of claim 8, wherein the first substrate comprises a first layer having at least one electrically conductive first portion and at least one electrically insulative second portion, the at least one electrically conductive first portion comprising the first deposited electrically conductive polymer material.

10. The structure of claim 8, wherein the first deposited electrically conductive polymer material is over at least one electrically insulative layer.

11. The structure of claim 8, wherein the second conductive feature comprises a second deposited electrically conductive polymer material, the first deposited electrically conductive polymer material bonded to the second deposited electrically conductive polymer material.

12. The structure of claim 8, wherein the second conductive feature comprises a metal material, the first deposited electrically conductive polymer material bonded to the metal material.

13. The structure of claim 8, wherein the first substrate includes a first electrically insulative material and the second substrate includes a second electrically insulative material directly bonded to the first electrically insulative material, the first deposited electrically conductive polymer material at least partially embedded in the first electrically insulative material.

14. The structure of claim 8, wherein the first deposited electrically conductive polymer material is optically transparent.

15. (canceled)

16. A method comprising:
providing a first substrate and a second substrate each comprising one or more electrically conductive surface portions and one or more electrically insulative surface portions, the one or more electrically conductive surface portions of at least one of the first substrate and the second substrate comprising an electrically conductive polymer material; and
hybrid bonding the first substrate and the second substrate with one another without an intervening adhesive, wherein hybrid bonding the first substrate and the second substrate comprises: contacting the one or more electrically conductive surface portions of the first substrate with the one or more electrically conductive surface portions of the second substrate and contacting the one or more electrically insulative surface portions of the first substrate with the one or more electrically insulative surface portions of the second substrate.

17. The method of claim 16, wherein providing the first substrate and the second substrate comprises depositing at least one dielectric layer onto the first substrate and/or the second substrate.

18. (canceled)

19. The method of claim 16, wherein providing the first substrate comprises:
depositing the electrically conductive polymer material onto the first substrate; and
patterning the electrically conductive surface portions to electrically isolate at least two regions of the electrically conductive surface portions on the first substrate from one another.

20. (canceled)

21. (canceled)

22. (canceled)

23. (canceled)

24. (canceled)

25. (canceled)

26. The method of claim 16, wherein providing the first substrate comprises:
patterning at least one dielectric layer at a top surface of the first substrate;
depositing an electrically conductive polymer material onto the patterned at least one dielectric layer of the first substrate, the electrically conductive surface portions of the first substrate comprising the electrically conductive polymer material; and
removing excess conductive polymer material from the top surface of the first substrate to electrically isolate at least two regions of the electrically conductive surface portions on the first substrate from one another.

27. (canceled)

28. (canceled)

29. (canceled)

30. The method of claim 16, wherein the electrically conductive surface portions of the first substrate comprise the electrically conductive polymer material and the electrically conductive surface portions of the second substrate do not comprise the electrically conductive polymer material.

31. The method of claim 16, wherein the electrically conductive polymer material comprises a hybrid conductive polymer material.

32. The method of claim 16, wherein providing the first substrate and the second substrate comprises:
depositing at least one dielectric material onto a substrate;
depositing at least one electrically conductive and adhesion enhancing material onto the at least one dielectric material;
depositing the electrically conductive polymer material onto the at least one electrically conductive and adhesion enhancing material;
patterning the electrically conductive polymer material and the at least one electrically conductive and adhesion enhancing material;
forming an electrically insulative adhesion enhancing layer over the patterned electrically conductive polymer material and the at least one dielectric material;
depositing an electrically insulative material onto the electrically insulative adhesion enhancing layer;
planarizing a surface of the electrically insulative material;
activating the planarized surface.

33. A structure comprising:
an integrated device die comprising a substrate comprising at least one electrically conductive contact pad at least partially embedded in an electrically insulative layer,
wherein the electrically conductive contact pad comprises an electrically conductive polymer material configured to electrically connect to an opposing conductive feature.

34. The structure of claim 33, wherein the electrically conductive polymer material is optically transparent.

35. (canceled)

36. The structure of claim 33, wherein the electrically insulative layer is planarized to directly bond to an opposing surface.
